(19) United States
(12) Patent Application Publication
(10) Pub. No.: US 2011/0284917 A1
(43) Pub. Date: Nov. 24, 2011

(54) COMPOUND SEMICONDUCTOR DEVICE AND METHOD FOR MANUFACTURING COMPOUND SEMICONDUCTOR DEVICE

(75) Inventors: Michiaki Murata, Kanagawa (JP); Hiroyuki Usami, Tokyo (JP); Yasuhisa Oota, Tokyo (JP); Hitoshi Takahashi, Tokyo (JP)

(73) Assignee: FUJI XEROX CO., LTD., Tokyo (JP)

(21) Appl. No.: 12/901,731

(22) Filed: Oct. 11, 2010

(30) Foreign Application Priority Data
May 20, 2010 (JP) 2010-115918

(51) Int. Cl. H01L 33/40

(52) U.S. Cl. 257/103; 438/46; 257/E33.002

(57) ABSTRACT

A compound semiconductor device includes: an Au alloy electrode, an interlayer insulating film, a metal interconnection, and an oxide film. The Au alloy electrode is formed on a compound semiconductor. The interlayer insulating film is formed on the Au alloy electrode. The metal interconnection is connected to the Au alloy electrode via a contact hole formed in the interlayer insulating film. The oxide film is formed at an interface between the Au alloy electrode and the interlayer insulating film, dominating component of the oxide film is a constituent element of the compound semiconductor.

### CROSS-REFERENCE TO RELATED APPLICATIONS

This application is based upon and claims priority under 35 USC 119 from Japanese Patent Application No. 2010-115918, filed May 20, 2010.

### BACKGROUND

1. Technical Field

The invention relates to a compound semiconductor device and a method for manufacturing the compound semiconductor device.

2. Related Art

A compound semiconductor device including GaAs, etc has been used widely as a light-emitting device. An electrode made of a gold (Au) alloy has been employed as an electrode for the compound semiconductor device in order to obtain good ohmic contact. Generally, the compound semiconductor device operates with directly applying a signal from an external to the electrode made of the Au alloy.

Meanwhile, in a high integrated micro-device such as a light emitting device array to which a logic circuit is mounted, for example, a self-scanning light emitting device (SLED) array, density of interconnections on a chip becomes high, and, thus, there occurs a need to form a combination of an interlayer insulating film, a contact hole and a fine metal-interconnection as in a conventional silicon integrated circuit. In this combination, the interlayer insulating film is formed on the electrode made of the Au alloy, but adhesion level between the Au alloy and the material of the interlayer insulating film is generally low, and, accordingly, there is a need for improving the adhesion level between the electrode made of the Au alloy and the interlayer insulating film.

### SUMMARY OF THE INVENTION

According to an aspect of the invention, a compound semiconductor device includes: an Au alloy electrode, an interlayer insulating film, a metal interconnection, and an oxide film. The Au alloy electrode is formed on a compound semiconductor. The interlayer insulating film is formed on the Au alloy electrode. The metal interconnection is connected to the Au alloy electrode via a contact hole formed in the interlayer insulating film. The oxide film is formed at an interface between the Au alloy electrode and the interlayer insulating film, dominating component of the oxide film is a constituent element of the compound semiconductor.

### BRIEF DESCRIPTION OF THE DRAWINGS

Exemplary embodiments of the invention will be described in detail based on the following figures, wherein:

FIG. 1 is a configuration view of a semiconductor device according to an exemplary embodiment of the invention;

FIG. 2 is a configuration view of a cathode electrode in FIG. 1;

FIG. 3 is a configuration view of a gate electrode in FIG. 1;

FIG. 4 is an illustrating view showing element distribution of the cathode electrode;

FIGS. 5A and 5B are microphotography views of the gate electrode;

FIG. 6 is a configuration view of the semiconductor device when a pinhole is generated;

FIG. 7 is a flow chart showing a manufacturing process according to an exemplary embodiment of the invention;

FIG. 8 is a configuration view (a first view) showing the manufacturing process according to the exemplary embodiment of the invention;

FIG. 9 is a configuration view (a second view) showing the manufacturing process according to the exemplary embodiment of the invention;

FIG. 10 is a configuration view (a third view) showing the manufacturing process according to the exemplary embodiment of the invention;

FIG. 11 is a configuration view (a fourth view) showing the manufacturing process according to the exemplary embodiment of the invention;

FIG. 12 is a configuration view (a fifth view) showing the manufacturing process according to the exemplary embodiment of the invention;

FIG. 13 is a configuration view (a sixth view) showing the manufacturing process according to the exemplary embodiment of the invention;

FIG. 14 is a configuration view (a seventh view) showing the manufacturing process according to the exemplary embodiment of the invention; and

FIG. 15 is a configuration view (an eighth view) showing the manufacturing process according to the exemplary embodiment of the invention.

### DETAILED DESCRIPTION

Below, an exemplary embodiment of the invention will be described in which a light emitting device in a self-scanning light emitting device (SLED) array mounted onto a print head of an image formation apparatus is set forth as one example of a compound semiconductor device. However, the semiconductor device is not limited to the light emitting device, but, rather, the invention may be applied to other semiconductor devices including non-light-emitting devices.

1. A Basic Configuration of the Semiconductor Device

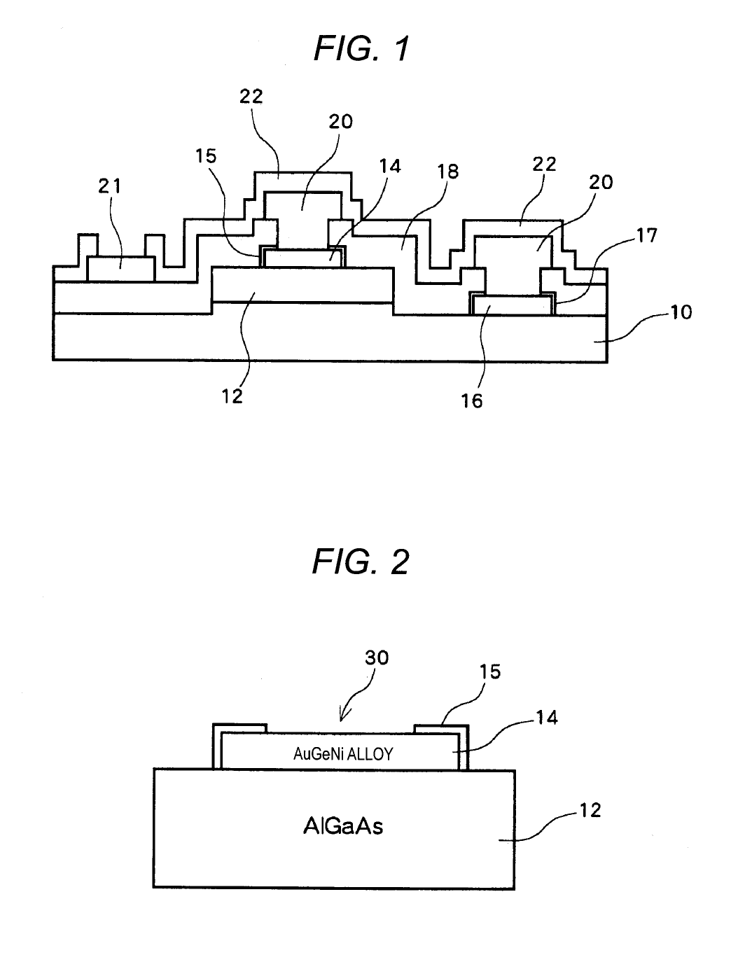

FIG. 1 shows a configuration of any one of a plurality of light emitting devices of which a self-scanning light emitting device (SLED) array mounted onto the print head of the image formation apparatus is comprised. The light emitting device, to be specific, is a light emitting thyristor, and a plurality of the light emitting thyristor are controlled so that they turn on/off on a basis of one set (or one block).

In FIG. 1, the compound semiconductor device includes an AlGaAs gate semiconductor layer 10 formed on a semiconductor substrate; a AlGaAs cathode semiconductor layer 12 formed on a predetermined region of the AlGaAs gate semiconductor layer 10; an Au alloy cathode electrode 14 formed on the AlGaAs cathode semiconductor layer 12; an Au alloy gate electrode 16 formed on the AlGaAs gate semiconductor layer 10; an interlayer insulating film 18; Al interconnections 20 formed on the cathode electrode 14 and the gate electrode 16; a pad 21; and a protection film 22.

The cathode electrode 14 and the gate electrode 16 are made of different Au alloys from each other, and, for example, the cathode electrode 14 is made of AuGeNi while the gate electrode 16 is made of AuSbZn.

The interlayer insulating film 18 is a silicon oxide film formed by for example a CVD method, and contact holes are formed in the interlayer insulating film 18 on the cathode electrode 14 and the gate electrode 16. In such a device, the adhesions between the Au alloy cathode electrode 14 and the interlayer insulating film 18 and between the Au alloy gate electrode 16 and the interlayer insulating film 18 are problematic. Accordingly, this embodiment improves the adhesions by forming oxide films 15, 17 at surfaces of the Au alloy cathode and gate electrodes 14, 16 respectively so that the oxide film 15 is disposed at an interface between the cathode electrode 14 and the interlayer insulating film 18 and, at the same time, the oxide film 17 is disposed at an interface between the gate electrode 16 and the interlayer insulating film 18.

2. A Configuration of the Cathode Electrode

FIG. 2 is an enlarged view of the Au alloy cathode electrode 14. The cathode electrode 14 is made of the AuGeNi alloy and is formed on the cathode semiconductor layer 12. The oxide film 15 is formed at and around the surface of the cathode electrode 14. A portion of the oxide film 15, that is, the oxide film 15 in a region on which the Al interconnection 20 is to be formed is removed, and, thus, an ohmic contact between the Al interconnection 20 and the cathode electrode 14 is obtained. The oxide film 15 in the region on which the Al interconnection 20 is to be formed is removed (in other words, an opening of the oxide film 15 is formed) by an etching treatment which, at the same time, forms the contact holes in the interlayer insulating film 18 as will be described later.

The oxide film 15 is formed by annealing the AuGeNi cathode electrode 14 formed on the AlGaAs cathode semiconductor layer 12 under oxidizing gas. That is, after forming the AuGeNi cathode electrode 14 on the AlGaAs cathode semiconductor layer 12, the resultant structure has been subjected under the oxidizing gas to the annealing treatment, and, in consequence, the Al or Ga which is the constituent element of the underlying cathode semiconductor layer 12 diffuses into the AuGeNi alloy, and is oxidized at the surface of the AuGeNi alloy layer 14, so that the oxide film 15 is formed at the surface of the cathode electrode 14. This oxide film 15 formed at and around the surface of the cathode electrode 14 improves the adhesion between the cathode electrode 14 and the interlayer insulating film 18.

3. A Configuration of the Gate Electrode

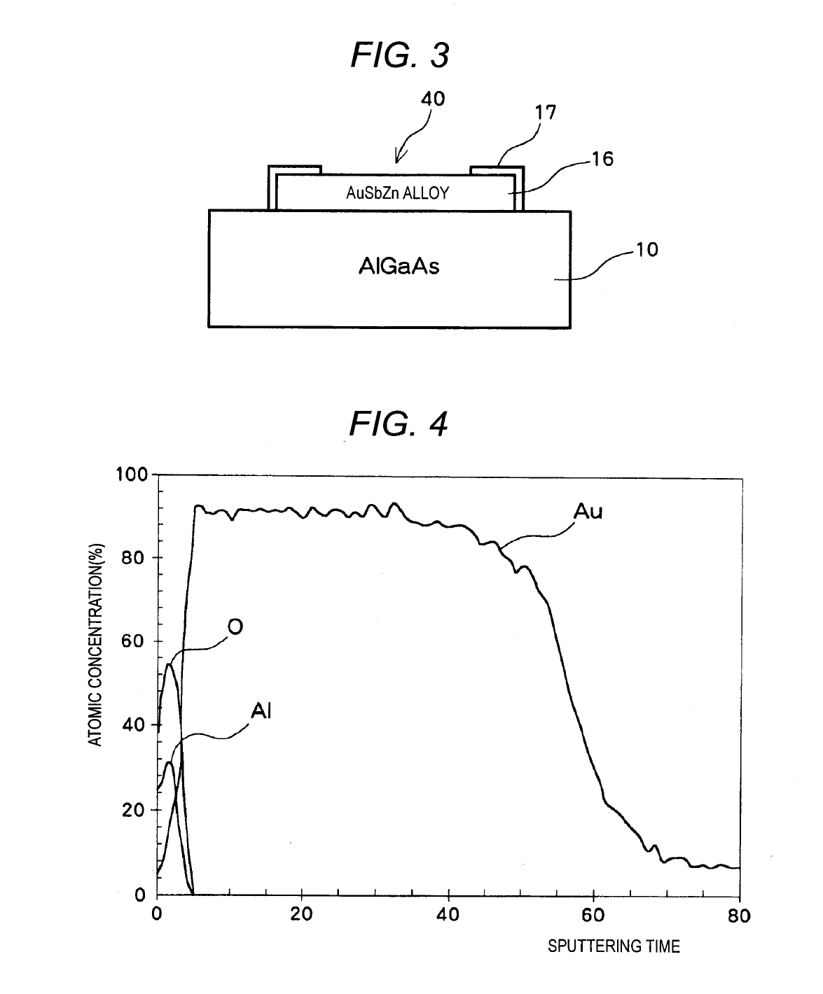

FIG. 3 is an enlarged view of the Au alloy gate electrode 16. The gate electrode 16 is made of the AuSbZn alloy and is formed on the gate semiconductor layer 10. The oxide film 17 is formed at and around the surface of the gate electrode 16. A portion of the oxide film 17, that is, the oxide film 17 in a region on which the Al interconnection 20 is to be formed is removed, and, thus, an ohmic contact between the Al interconnection 20 and the gate electrode 16 is obtained. The oxide film 17 in the region on which the Al interconnection 20 is to be formed is removed (in other words, an opening of the oxide film 17 is formed) by an etching treatment which, at the same time, forms the contact holes in the interlayer insulating film 18 as in forming the opening of the oxide film 15.

The oxide film 17 is formed by annealing the AuSbZn gate electrode 16 formed on the AlGaAs gate semiconductor layer 10 under the oxidizing gas. That is, after forming the AuSbZn gate electrode 16 on the AlGaAs gate semiconductor layer 10, the resultant structure has been subjected under the oxidizing gas to the annealing treatment, and, in turn, the Al or Ga which is the constituent element of the underlying gate semiconductor layer 10 diffuses into the AuSbZn alloy, and is oxidized at the surface of the AuSbZn alloy layer 16, so that the oxide film 17 is formed at the surface of the gate electrode 16. This oxide film 17 formed at and around the surface of the gate electrode 16 improves the adhesion between the gate electrode 16 and the interlayer insulating film 18.

4. The Oxide Films of the Cathode and Gate Electrodes

FIG. 4 shows an analysis result of the cathode electrode 14 annealed so as to be oxidized. At this figure, a lateral axis represents a sputtering time (minute) during which the surface of the cathode electrode 14 has been subjected to a sputtering treatment, and corresponds to a depth from the surface of the cathode electrode 14. A vertical axis represents atomic concentration %. In a case that the sputtering time is short, at the surface region of the cathode electrode 14, the atomic concentrations of oxygen atoms O and aluminum atoms Al become high. Thereafter, as the sputtering time increases, the atomic concentrations of the oxygen atoms and aluminum atoms Al decreases, whereas the atomic concentration of gold atoms Au becomes high. This gives evidence that the oxide film whose dominating component is Al is formed at the surface of the cathode electrode 14.

In addition, the applicant(s) of the invention analyzed the gate electrode 16 annealed so as to be oxidized, in the same way as in analyzing the oxidization-annealed cathode electrode 14. In a case that the sputtering time is short, at the surface region of the gate electrode 16, the atomic concentrations of oxygen atoms O and gallium atoms Ga become high. Thereafter, as the sputtering time increases, the atomic concentrations of the oxygen atoms O and gallium atoms Ga decreases, whereas the atomic concentration of gold atoms Au becomes high. This gives evidence that the oxide film whose dominating component is Ga is formed at the surface of the gate electrode 16.

It is presumed that the facts that the oxide film 15 whose dominating component is Al is formed at the surface of the cathode electrode 14, and the oxide film 17 whose dominating component is Ga is formed at the surface of the gate electrode 16 result from that the constituent elements of the underlying AlGaAs diffuse into the Au alloy and then is oxidized with the oxidation annealing. Further, such a presumption is based on an idea that the underlying AlGaAs layers of the cathode and gate electrodes 14, 16 respectively have different compositions from each other, and thicknesses of the cathode and gate electrodes 14, 16 are different from each other.

In this way, when the cathode and gate electrodes 14, 16 have been subjected under the oxidizing gas to the annealing treatment, the oxide films 15, 17 whose dominating components are different elements from each other are formed at the surfaces of the cathode and gate electrodes 14, 16 respectively. Such oxide films 15, 17 not only improve the adhesion to the interlayer insulating film 18, but also suppress deficiency errors, i.e., so called voids in the cathode and gate electrodes 14, 16.

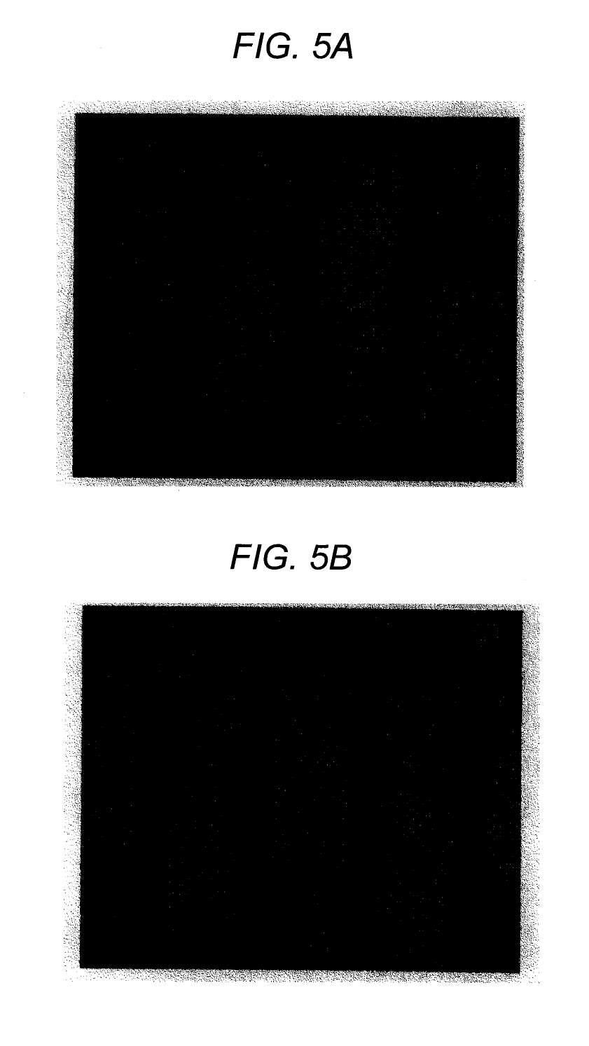

FIG. 5 shows a microphotography plan view of the oxidation-annealed gate electrode 16. FIG. 5A shows the microphotography plan view of the gate electrode 16 annealed under N₂ gas not containing oxygen, while FIG. 5B shows the microphotography plan view of the oxidation-annealed gate electrode 16. As shown in FIG. 5A, in the gate electrode 16 annealed under N₂ gas not containing oxygen, in particular, at sides of the gate electrode 16, the voids are formed. It is believed that this is due to flowing of the Au atoms which is the main component of the gate electrode 16. To the contrary, as shown in FIG. 5B, any voids are substantially not formed in the oxidation-annealed gate electrode 16 at the surface of which the oxide film 17 is formed. It is believed that this results from that the flowing of the Au atoms is suppressed due to the relatively hard oxide film 17 or the oxygen atoms enter into grain boundaries of the Au atoms so as to suppress the movement of the Au atoms.

Moreover, when the oxide films 15, 17 are formed on the surfaces of the cathode and gate electrodes 14, 16 respectively, such oxide films 15, 17 serve as insulating films, thereby improving dielectric breakdown voltage.

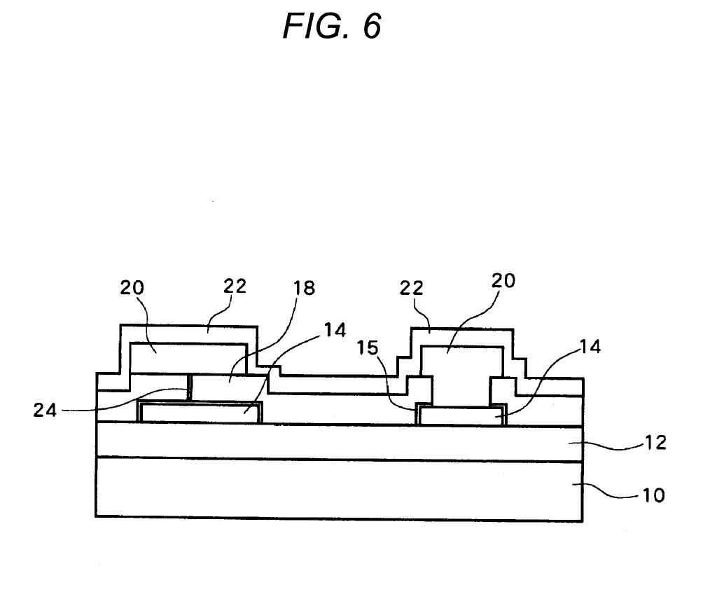

FIG. 6 is a configuration view of the semiconductor device when a pinhole is generated in the interlayer insulating film 18 formed on the cathode electrode 14. Because as mentioned above, the portion of the oxide film 15 in the region of the surface of the cathode electrode 14 on which the contact hole is to be formed is removed in forming the contact hole in the interlayer insulating film 18, the oxide film 15 covers an entire surface of the cathode electrode 14 except the region of the surface on which the contact hole is to be formed. For this reason, in a case that in forming the interlayer insulating film 18 on the cathode electrode 14 using a CVD method, the pinhole 24 is formed in the interlayer insulating film 18 due to film formation failures, the dielectric breakdown voltage is not lowered but is kept the same in that the surface of the cathode electrode 14 is covered in an insulation way with the oxide film 15, and, hence, the Al interconnection 20 is not in electrical contact with the cathode electrode 14. In a region at which the pinhole 12 is not formed, the dielectric breakdown voltage improves due to the two-layered insulation structure consisted of the oxide film 15 and the interlayer insulating film 18.

5. A Method for Manufacturing the Compound Semiconductor Device

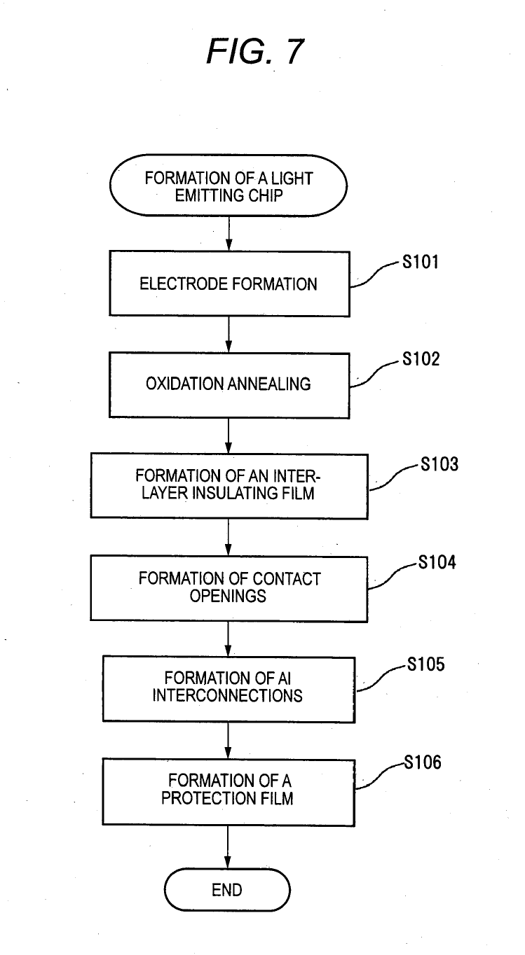

FIG. 7 is a flow chart showing a manufacturing process of a light emitting device according to an exemplary embodiment of the invention.

First, after forming the gate semiconductor layer 10 and the cathode semiconductor layer 12 on the semiconductor substrate, the Au alloy cathode electrode 14 and the Au alloy gate electrode 16 are formed using a depositing method and a resist lift-off method (S101).

Next, the resultant structure has been subjected under the oxidizing gas to the annealing treatment at given temperature (S102). By the oxidation annealing, the constituent elements of the underlying layer of the cathode electrode 14 diffuses into the Au alloy and then are oxidized at the surface thereof, so that the oxide film 15 is formed. Similarly, by the oxidation annealing, the constituent elements of the underlying layer of the gate electrode 16 diffuses into the Au alloy and then are oxidized at the surface thereof, so that the oxide film 17 is formed. By this oxidation annealing, the oxide films 15, 17 are formed, and, at the same time, there are formed an ohmic contact between the cathode electrode 14 and the underlying cathode semiconductor layer 12 thereof as well as an ohmic contact between the gate electrode 16 and the underlying gate semiconductor layer 10 thereof.

Thereafter, the interlayer insulating film 18 such as the silicon oxide film, etc is formed using the CVD method (S103).

In the following, the contact holes are formed in the interlayer insulating film 18 and on the cathode and gate electrodes 14, 16 using photolithography and reactive ion etching methods (S104). At this time, the portion of the oxide film 15 at the surface of the cathode electrode 14 and the portion of the oxide film 17 at the surface of the gate electrode 16 are removed at the same time. Next, the Al interconnections 20 are formed as the metallization in the contact holes (S105). Further, the pad 21 is formed.

Last, the protection film 22 is formed and a portion thereof on the pad 21 is removed to form a contact hole (S106).

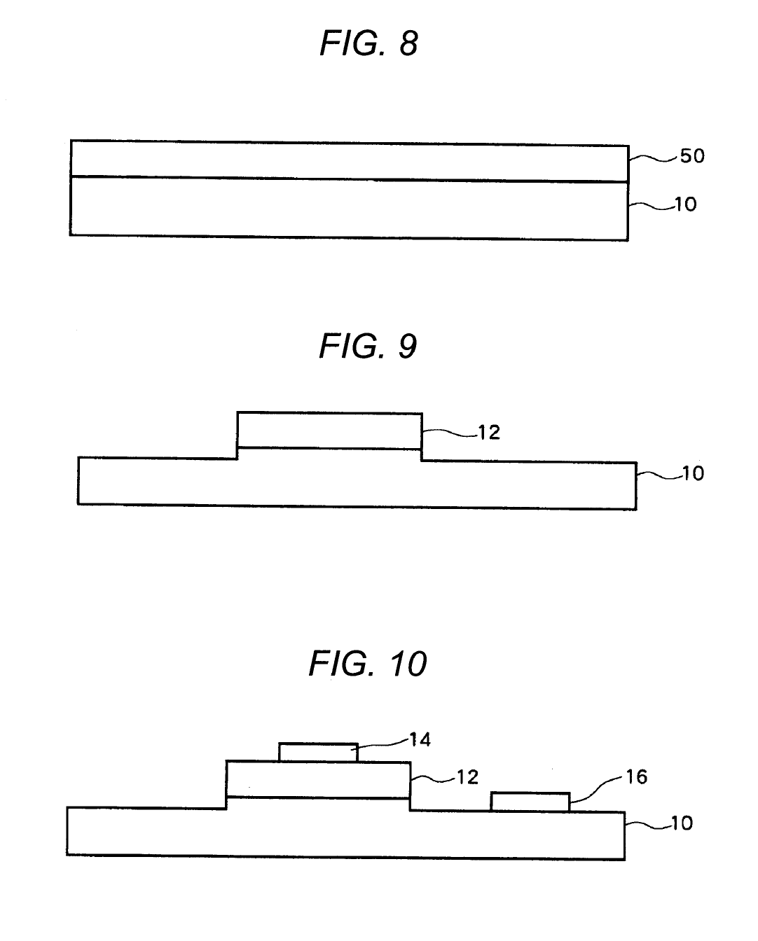

FIG. 8 to FIG. 15 shows a specific manufacturing process of the light emitting device according to the exemplary embodiment of the invention. First, as shown in FIG. 8, the AlGaAs gate semiconductor layer 10 and then the AlGaAs cathode semiconductor layer 50 are stacked sequentially on the semiconductor substrate.

Next, as shown in FIG. 9, portions of the AlGaAs gate semiconductor layer 10 and the AlGaAs cathode semiconductor layer 50 are etched away so that the AlGaAs cathode semiconductor layer 12 remains in a region on which the cathode electrode is to be formed.

Thereafter, as shown in FIG. 10, the Au alloy cathode electrode 14 made of the AuGeNi alloy is formed in a patterning way on the AlGaAs cathode semiconductor layer 12 using deposition and resist lift-off methods, and the Au alloy gate electrode 16 made of the AuSbZn alloy is formed in a pattering way on the AlGaAs gate semiconductor layer 10 using the deposition and resist lift-off methods.

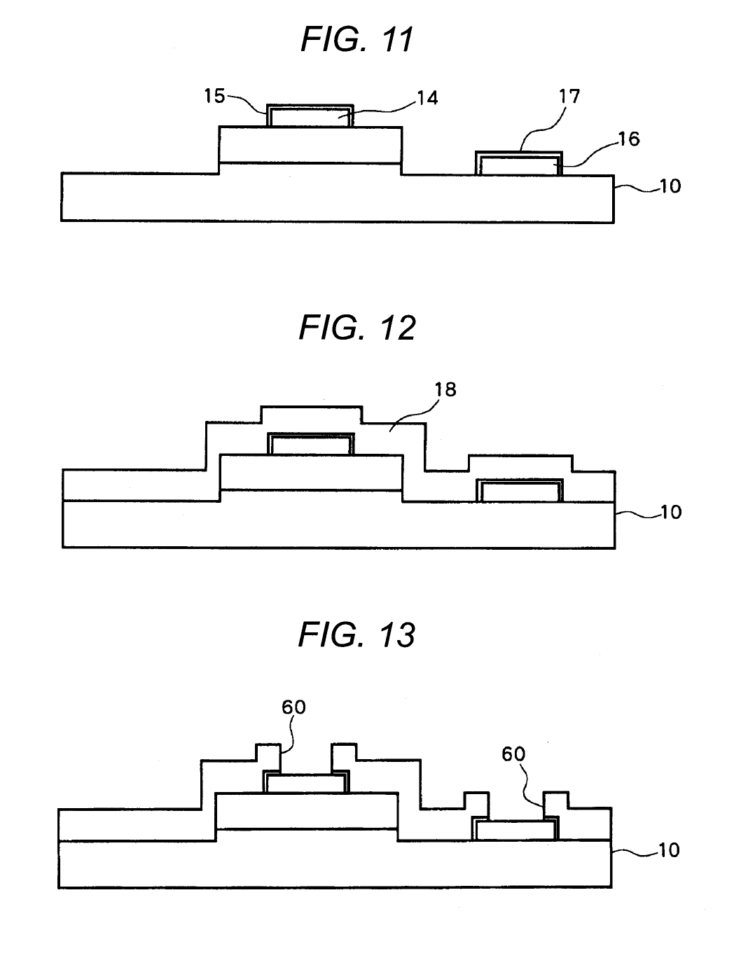

Subsequently, as shown in FIG. 11, by performing the oxidation annealing of the resultant structure under a predetermined condition, the oxide film 15 whose dominating component is Al is formed at the surface of the Au alloy cathode electrode 14, and, at the same time, the oxide film 17 whose dominating component is Ga is formed at the surface of the Au alloy gate electrode 16. For example, the oxidation annealing under the predetermined condition is the annealing for 10 minutes at 400° C. temperature under the atmosphere of N₂ (10 slm) and O₂ (0.5 slm). Although all of the underlying semiconductor substrates of the cathode and gate electrodes 14, are made of AlGaAs, composition ratios of Al in the underlying compound semiconductor layers of the cathode and gate electrodes 14, 16 are different from each other, and thicknesses of the cathode and gate electrodes 14, 16 are different from each other as well, so that the elements appearing at the surfaces of the cathode and gate electrodes 14, 16 are different from each other. Anyway, the constituent elements of the underlying AlGaAs semiconductor layers diffuse into the Au alloy of the electrodes thereon and are oxidized at the surfaces of the electrodes, so that the oxide films 15, are formed. This phenomenon that the elements of the underlying layers diffuse into the films thereon and, in turn, the oxide films are formed at the film surfaces opposite to and facing away the underlying layers is similar to the oxidation phenomenon of a tungsten-polycide (a two-layered structure consisted of a WSi₂ film and a polysilicon film) used in the process for manufacturing the silicon integrated circuit.

The oxide film 15 whose dominating component is Al and which is formed by the oxidation annealing, and the oxide film 17 whose dominating component is Ga and which is formed by the oxidation annealing have not only the excellent adhesions to the underlying Au alloy layers but also the excellent adhesions to the interlayer insulating film 18 which will be formed later. Furthermore, in this embodiment, in that the vapor gas easily reaches the sides of the cathode and/or gate electrodes 14, 16 and/or inner space of micro pores in the cathode and/or gate electrodes 14, 16, the oxide films 15, 17 are formed with high density at and around the entire surfaces of the cathode and/or gate electrodes 14, 16, resulting in excellent coverage. In the meanwhile, although in a region at which the Au alloy layers are not formed, the semiconductor substrate is exposed to the oxidizing gas, just a thin natural oxidation film is formed at the surface of the substrate, and this thin natural oxidation film does not cause a particular problem and has excellent adaptability with the compound semiconductor manufacturing process.

Seeing that as mentioned above, the oxidation annealing treatment serves as the heating treatment for forming the ohmic contacts between the cathode and gate electrodes 14, 16 and the underlying semiconductor substrate, a separate and distinct heating treatment from the oxidation annealing treatment and for forming the ohmic contacts is not necessary. In other words, if a heating treatment is performed in order to form the ohmic contacts, the oxide films 15, 17 are formed at the surfaces of the cathode and gate electrodes 14, 16 at the same time as the heating treatment.

Next, as shown in FIG. 12, the silicon oxide film as the interlayer insulating film 18 is formed over the entire surface of the semiconductor substrate using a CVD method.

Subsequently, as shown in FIG. 13, the contact holes 60 are formed by removing the interlayer insulting film 18 on the cathode electrode 14 and on the gate electrode 16 using the photolithography and reactive ion etching methods. At this time, the oxide film 15 formed at the surface of the cathode electrode 14 and the oxide film 17 formed at the surface of the gate electrode 16 are, at the same time, removed as well.

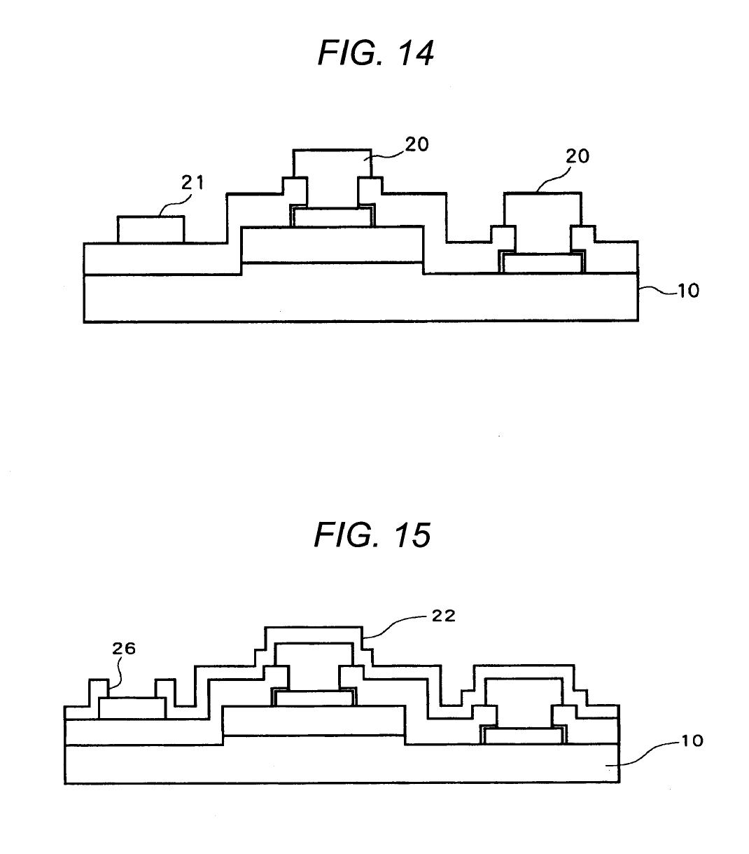

In the following, as shown in FIG. 14, the Al interconnections 20 and pad 21 are formed in the contact holes 60 and in a pad formation region respectively.

Last, as shown in FIG. 15, the protection film 22 is formed over the entire surface of the resultant structure and then an opening 26 is formed at the pad formation region.

According to this embodiment, by forming the oxide films 15, 17 at the surfaces of the cathode and gate electrodes 14, 16 respectively using the oxidation annealing treatment, the adhesions between the cathode electrode 14 and the interlayer insulating film 18 and between the gate electrode 16 and the interlayer insulating film 18 may improve. Further, the voids are prevented, due to the oxide film 17, from being formed in the gate electrode 16. Furthermore, the dielectric breakdown voltage of the light emitting device may improve due to the oxide films 15, 17. Moreover, in this embodiment, regarding the oxidation annealing treatment used in forming the oxide films 15, 17, an annealing treatment is performed in forming the ohmic contacts with the underlying layer of the cathode and gate electrodes 14, 16, and, thus, the oxidation annealing treatment is realized just by introducing the oxidizing gas in the annealing treatment, resulting in no increase of the steps in the oxidation annealing treatment and the good adaptability with the existing semiconductor manufacturing process.

6. Variations

Although until now, the embodiment of the invention has been described, the invention is not limited to this embodiment, but, rather, various variations are possible.

For example, although in the above-mentioned embodiment, the condition for the oxidation annealing treatment is the annealing for 10 minutes at 400° C., temperature under the atmosphere of N₂ and O₂, the annealing time and temperature are not limited to those, but, rather, different annealing time and temperature may be possible. A particular limitation is not imposed on the thicknesses of the oxide films 15, 17, which, hence, may vary depending on the adhesion and dielectric breakdown voltage required.

In addition, although in the embodiment, the oxygen gas is employed as the oxidizing gas, the oxidizing gas is not limited to it, but, rather, any gas including oxygen may be used. For example, H₂O gas or N₂O gas may be employed.

Besides, although in the embodiment, the AlGaAs substrate is used as the semiconductor substrate, the semiconductor substrate is not limited to it, and, for example, a GaAs substrate may be employed. In a latter case, the dominating component of the oxide films 15, 17 becomes Ga.

Furthermore, although in the embodiment, the oxide film contains Al as its dominating component, while the oxide film 17 contains Ga as its dominating component, the invention is not limited to this. For example, the oxide film 15 may contain Ga as its dominating component. Besides, the oxide film 17 may contain Al as its dominating component. Further, a combination of an oxide film containing Al as its dominating component and an oxide film containing the constituent element (Ge or Ni) of the Au alloy as its dominating component may be formed as the oxide film 15; or only the oxide film containing the constituent element (Ge or Ni) of the Au alloy as its dominating component may be formed as the oxide film 15. This is equally applied to the oxide film 17, and, to be specific, a combination of an oxide film containing Ga as its dominating component and an oxide film containing the constituent element (Sb or Zn) of the Au alloy as its dominating component may be formed as the oxide film 17; or only the oxide film containing the constituent element (Sb or Zn) of the Au alloy as its dominating component may be formed as the oxide film 17. In the specification, the “dominating component” generally means an element having its dominating or prevailing composition ratio in the oxide film among elements (excluding oxygen) contained in the oxide film, and, more particularly, “dominating” means that amount of the constituent element of the compound semiconductor is larger than a half of amount of the constituent element(s) of the oxide film. The dominating component, in most cases, may be one element, but it is not always that case, and the dominating component may be a plurality of elements.

The foregoing description of the exemplary embodiment of the present invention has been provided for the purpose of illustration and description. It is not intended to be exhaustive or to limit the invention to the precise forms disclosed. Obviously, many modifications and various will be apparent to practitioners skilled in the art. The embodiments were chosen and described in order to best explain the principles of the invention and its practical application, thereby enabling other skilled in the art to understand the invention for various embodiments and with the various modifications as are suited to the particular use contemplated. It is intended that the scope of the invention be defined by the following claims and their equivalents.

What is claimed is:

1. A compound semiconductor device comprising:
an Au alloy electrode that is formed on a compound semiconductor;
an interlayer insulating film that is formed on the Au alloy electrode;
a metal interconnection that is connected to the Au alloy electrode via a contact hole formed in the interlayer insulating film; and
an oxide film that is formed at an interface between the Au alloy electrode and the interlayer insulating film, dominating component of the oxide film is a constituent element of the compound semiconductor.

2. The compound semiconductor device according to claim 1, wherein the compound semiconductor is AlGaAs, and the dominating component of the oxide film is Al.

3. The compound semiconductor device according to claim 1, wherein the compound semiconductor is AlGaAs, and the dominating component of the oxide film is Ga.

4. The compound semiconductor device according to claim 1, wherein the compound semiconductor is GaAs, and the dominating component of the oxide film is Ga.

5. A method for manufacturing a compound semiconductor device comprising:
forming an Au alloy electrode on a compound semiconductor;
forming, at a surface of the Au alloy electrode, an oxide film whose dominating component is a constituent element of the compound semiconductor by annealing the Au alloy electrode under oxidizing gas;
forming an interlayer insulating film on the annealed Au alloy electrode;
forming a contact hole in the interlayer insulating film and, at the same time, removing a portion of the oxide film; and
forming a metal interconnection in the contact hole.
